(19) United States
(12) Patent Application Publication
(10) Pub. No.: US 2015/0035037 A1
(43) Pub. Date: Feb. 5, 2015

(54) SEMICONDUCTOR MEMORY DEVICE AND METHOD FOR MANUFACTURING SAME

(71) Applicant: Kabushiki Kaisha Toshiba, Minato-ku (JP)

(72) Inventors: Haruka SAKUMA, Yokkaichi (JP); Yoshiaki FUKUZUMI, Yokkaichi (JP)

(73) Assignee: Kabushiki Kaisha Toshiba, Minato-ku (JP)

(21) Appl. No.: 14/445,247

(22) Filed: Jul. 29, 2014

(30) Foreign Application Priority Data
Jul. 30, 2013 (JP) 2013-157354

(51) Int. Cl. H01L 27/115

(52) U.S. Cl. CPC H01L 27/11551; H01L 27/11578
USPC 257/314; 438/268

(57) ABSTRACT

According to one embodiment, the select transistor is provided between a memory array region and the layer selection portion. The channel body and the charge storage film are provided in the memory array region. The select transistor includes a gate electrode provided on a side wall of one of the line portions between the memory array region and the layer selection portion; and a gate insulator film provided between the gate electrode and the line portions. The gate electrode extends in the stacking direction.

### CROSS-REFERENCE TO RELATED APPLICATION

This application is based upon and claims the benefit of priority from Japanese Patent Application No. 2013-157354, filed on Jul. 30, 2013; the entire contents of which are incorporated herein by reference.

### BACKGROUND

A memory device having a three-dimensional structure has been proposed in which memory holes are made in a stacked body in which insulating layers are multiply stacked alternately with electrode layers that function as control gates of memory cells, and silicon bodies used to form channels are provided on the side walls of the memory holes with a charge storage film interposed between the silicon bodies and the side walls.

In such a three-dimensional structure memory device, it has been proposed to perform the erasing operation of data by block units that include multiple memory cells. In such a case, when one block size increases as the number of stacks of the electrode layers increases, the memory cells (the unselected cells) that undergo voltage stress in the erasing also increase; and there is a risk that read disturbance may increase.

### BRIEF DESCRIPTION OF THE DRAWINGS

FIG. 1 is a schematic plan view of a semiconductor memory device of a first embodiment;

FIG. 2 is a schematic perspective view of a memory cell array of a semiconductor memory device of an embodiment;

FIG. 3 is a schematic cross-sectional view of a memory cell of a semiconductor memory device of an embodiment;

FIG. 4 is an enlarge schematic view of a select transistor of a semiconductor memory device of an embodiment;

FIGS. 5A and 5B are schematic cross-sectional views of a semiconductor memory device of an embodiment;

FIG. 6 is a schematic cross-sectional view of a semiconductor memory device of an embodiment;

FIGS. 7A and 7B are schematic cross-sectional views showing a method for manufacturing a select transistor of the semiconductor memory device of the first embodiment;

FIGS. 8A and 8B are schematic cross-sectional views showing a method for manufacturing a select transistor of a semiconductor memory device of a second embodiment;

FIGS. 9A and 9B are schematic cross-sectional views showing a method for manufacturing a select transistor of a semiconductor memory device of a third embodiment;

FIG. 10 is a schematic plan view of a semiconductor memory device of a fourth embodiment; and

FIG. 11 is a schematic plan view of a semiconductor memory device of a fifth embodiment.

### DETAILED DESCRIPTION

According to one embodiment, a semiconductor memory device includes a substrate, a stacked body, a channel body, a charge storage film, and a select transistor. The stacked body includes a plurality of electrode layers and a plurality of insulating layers stacked alternately on the substrate. The stacked body includes a plurality of line portions and a layer selection portion. The plurality of line portions extend in a first direction in a plane parallel to the substrate. The layer selection portion includes a plurality of contact portions connected to the electrode layers at an end of the line portions in the first direction. The channel body is provided in the line portions to extend in a stacking direction of the stacked body. The charge storage film is provided between the channel body and the electrode layers. The select transistor is provided between a memory array region and the layer selection portion. The channel body and the charge storage film are provided in the memory array region. The select transistor includes a gate electrode provided on a side wall of one of the line portions between the memory array region and the layer selection portion; and a gate insulator film provided between the gate electrode and the line portions. The gate electrode extends in the stacking direction.

Embodiments will now be described with reference to the drawings. Similar components are marked with like reference numerals in the drawings.

### First Embodiment

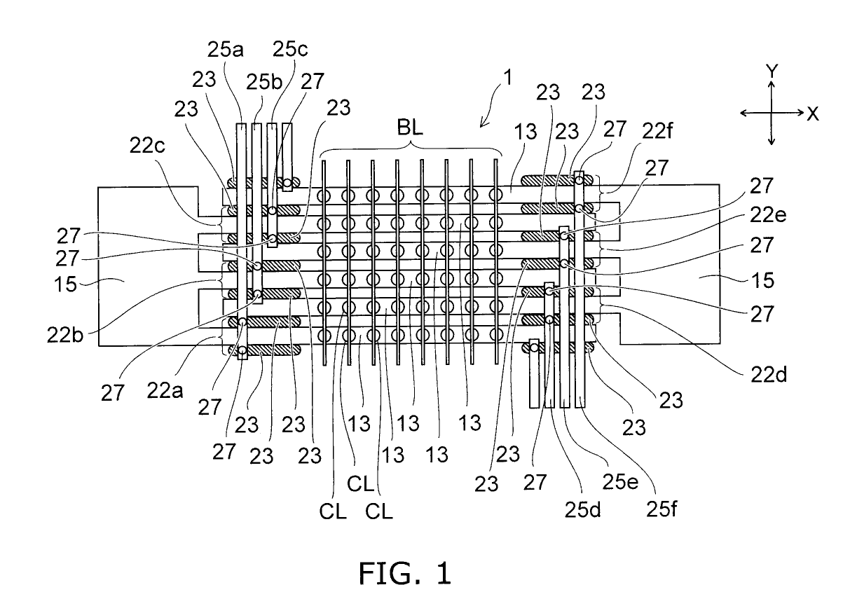

FIG. 1 is a schematic plan view of a semiconductor memory device of a first embodiment.

The semiconductor memory device of the first embodiment includes a memory cell array 1, a layer selection portion 15, and select transistors 22a to 22f provided in a region between the memory cell array 1 and the layer selection portion 15.

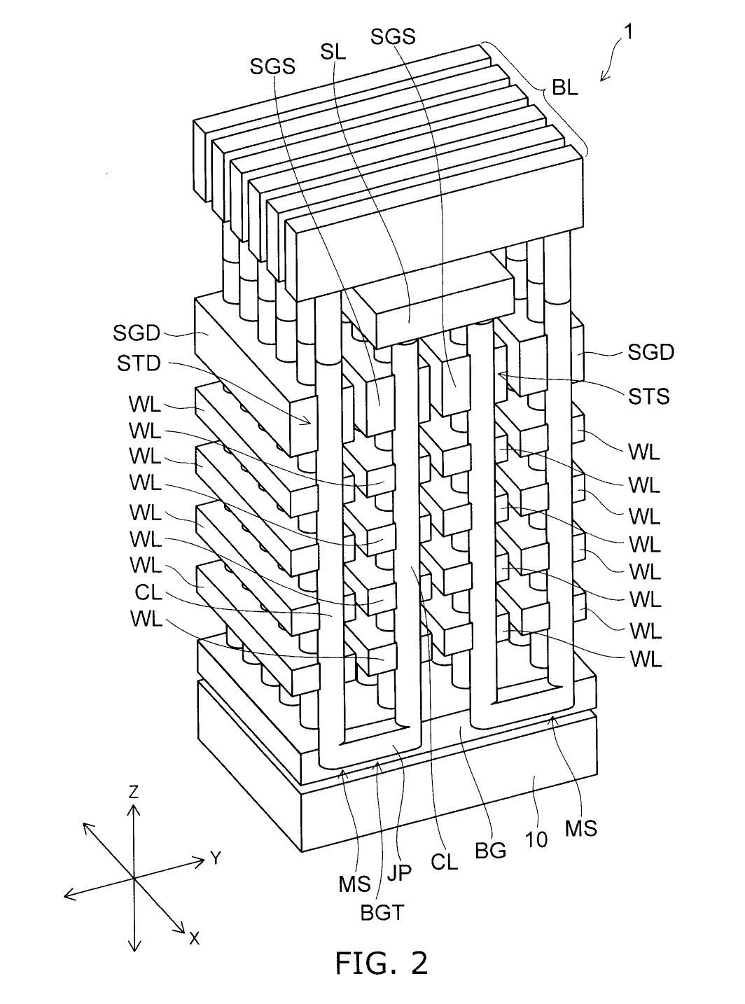

The memory cell array 1, the layer selection portion 15, and the select transistors 22a to 22f are provided on a substrate 10 shown in FIG. 2. The substrate 10 is, for example, a silicon substrate.

FIG. 2 is a schematic perspective view of the memory cell array 1. In FIG. 2, the insulating portions are not shown for easier viewing of the drawing.

In FIG. 2, two mutually-orthogonal directions in a plane parallel to a major surface of the substrate 10 are taken as an X-direction (a first direction) and a Y-direction (a second direction); and a direction orthogonal to both the X-direction and the Y-direction is taken as a Z-direction (a third direction or a stacking direction).

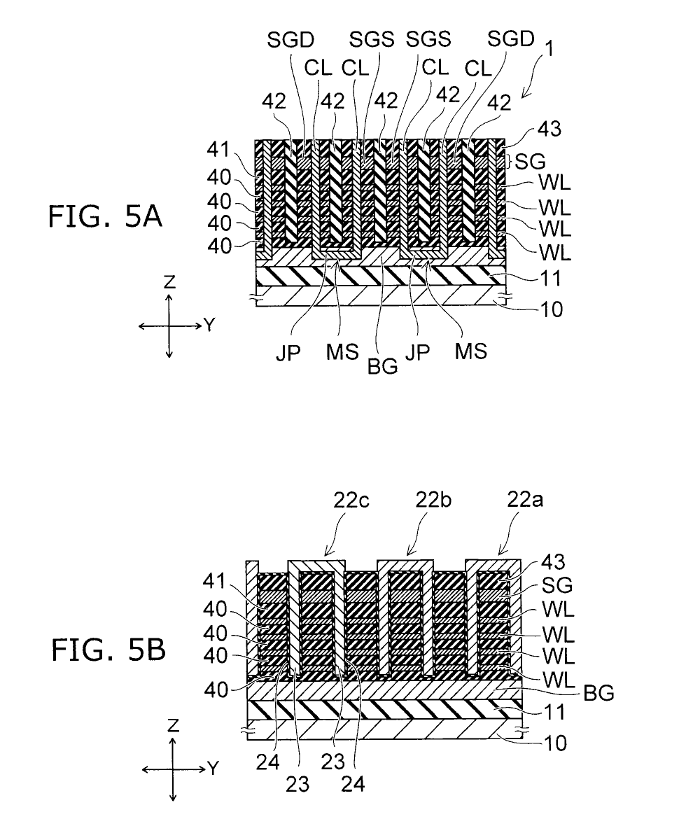

FIG. 5A is a schematic cross-sectional view of the memory cell array 1. FIG. 5A corresponds to a cross section of FIG. 2 parallel to the YZ plane.

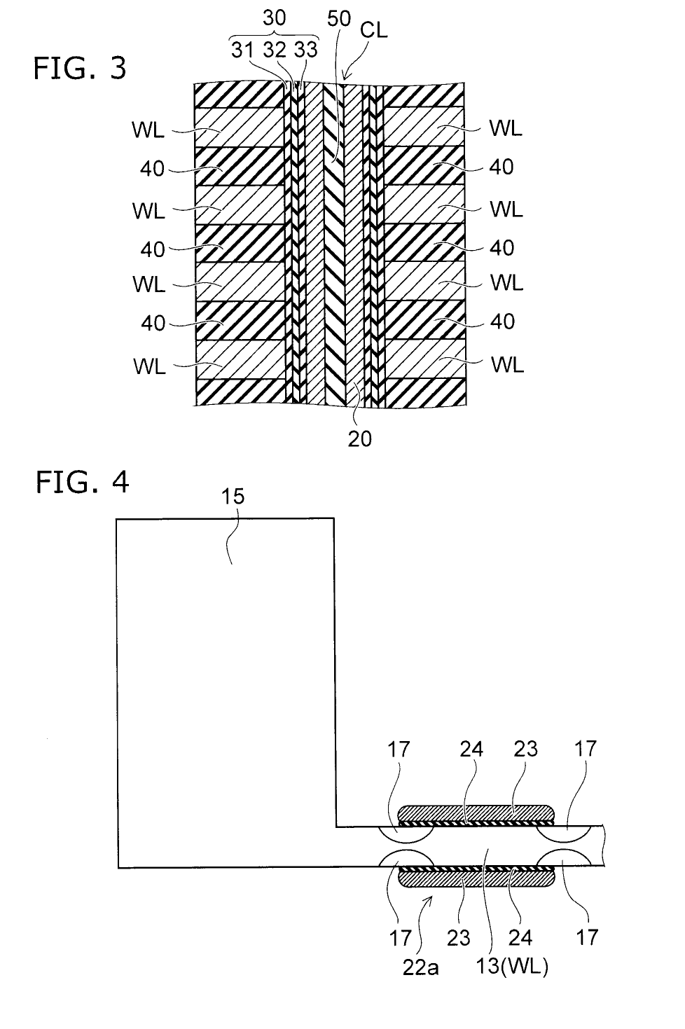

FIG. 3 is an enlarged schematic cross-sectional view of a portion of FIG. 5A where memory cells are provided.

The memory cell array 1 includes a stacked body in which multiple electrode layers WL and multiple insulating layers 40 are stacked alternately one layer at a time.

The stacked body is provided on a back gate BG that is used as a lower gate layer. The number of layers of the electrode layers WL shown in the drawings is an example; and the number of layers of the electrode layers WL is arbitrary.

The back gate BG is provided on the substrate 10 with an insulating layer 11 (FIG. 5A) interposed. The back gate BG and the electrode layers WL are conductive layers, e.g., semiconductor layers. The back gate BG and the electrode layers WL are, for example, silicon layers into which an impurity is added.

The memory cell array 1 includes multiple memory strings MS. One memory string MS is formed in a U-shaped configuration that includes a pair of columnar portions CL extending in the Z-direction and a connecting portion JP that links the lower ends of the pair of columnar portions CL. The columnar portions CL are formed, for example, in circular columnar configurations that pierce the stacked body.

A drain-side selection gate SGD is provided at the upper end portion of one of the pair of columnar portions CL of the memory string MS having the U-shaped configuration; and a source-side selection gate SGS is provided at the upper end portion of the other of the pair of columnar portions CL of the memory string MS having the U-shaped configuration. The drain-side selection gate SGD and the source-side selection gate SGS that are used as upper selection gates are provided on the electrode layer WL of the uppermost layer with an insulating layer 41 (FIG. 5A) interposed between the drain-side selection gate SGD and the insulating layer 41 and between the insulating layer 41 and the source-side selection gate SGS.

The drain-side selection gate SGD and the source-side selection gate SGS are conductive layers, e.g., semiconductor layers. The drain-side selection gate SGD and the source-side selection gate SGS are, for example, silicon layers into which an impurity is added. In the following description, the drain-side selection gate SGD and the source-side selection gate SGS may be called simply the selection gate SG without differentiating.

The drain-side selection gate SGD and the source-side selection gate SGS are separated in the Y-direction by an insulating separation film 42 shown in FIG. 5A. The stacked body that is under the drain-side selection gate SGD and the stacked body that is under the source-side selection gate SGS are separated in the Y-direction by the insulating separation film 42. In other words, the stacked body between the pair of columnar portions CL of the memory string MS having the U-shaped configuration is divided in the Y-direction by the insulating separation film 42.

As shown in FIG. 5A, an insulating layer 43 is provided on the selection gates SG. A source line SL and a bit line BL shown in FIG. 2 are provided on the insulating layer 43.

The source line SL and the bit line BL are, for example, metal films. As shown in FIGS. 1 and 2, multiple bit lines BL are arranged in the X-direction; and each of the bit lines BL extends in the Y-direction.

A memory hole having a U-shaped configuration is made in the back gate BG and in the stacked body on the back gate BG. As shown in FIG. 3, a channel body 20 is provided inside the memory hole. The channel body 20 is, for example, a silicon film. The impurity concentration of the channel body 20 is lower than the impurity concentration of the electrode layers WL.

A memory film 30 is provided between the inner wall of the memory hole and the channel body 20. The memory film 30 includes a blocking film 31, a charge storage film 32, and a tunneling film 33. The blocking film 31, the charge storage film 32, and the tunneling film 33 are provided between the channel body 20 and the electrode layers WL in order from the electrode layer WL side.

The channel body 20 is provided in a tubular configuration; and the memory film 30 is provided in a tubular configuration around the outer circumferential surface of the channel body 20. The electrode layers WL are provided around the channel body 20 with the memory film 30 interposed between the channel body 20 and the electrode layers WL. A core insulating film 50 is provided inside the channel body 20.

The blocking film 31 contacts the electrode layers WL; the tunneling film 33 contacts the channel body 20; and the charge storage film 32 is provided between the blocking film 31 and the tunneling film 33.

The channel body 20 functions as the channels of the memory cells; and the electrode layers WL function as the control gates of the memory cells. The charge storage film 32 functions as a data storage layer that stores charge injected from the channel body 20. In other words, a memory cell having a structure in which a control gate is provided around a channel is formed at the intersection between the channel body 20 and each of the electrode layers WL.

The semiconductor memory device of the embodiment is a nonvolatile semiconductor memory device that can freely and electrically erase/program data and retain the memory content even when the power supply is OFF.

The memory cell is, for example, a charge trap memory cell. The charge storage film 32 has many trap sites that trap the charge and is, for example, a silicon nitride film.

The blocking film 31 is, for example, a silicon oxide film, a silicon nitride film, or a stacked film of a silicon oxide film and a silicon nitride film that prevents the charge stored in the charge storage film 32 from diffusing into the electrode layers WL.

The tunneling film 33 is used as a potential barrier when the charge is injected from the channel body 20 into the charge storage film 32 or when the charge stored in the charge storage film 32 diffuses into the channel body 20. The tunneling film 33 is, for example, a silicon oxide film, a silicon nitride film, a silicon oxynitride film, or a stacked film including a silicon oxide film, a silicon nitride film, and/or a silicon oxynitride film.

As shown in FIG. 2, a drain-side select transistor STD is provided at the upper end portion of one of the pair of columnar portions CL of the memory string MS having the U-shaped configuration; and a source-side select transistor STS is provided at the upper end portion of the other of the pair of columnar portions CL of the memory string MS having the U-shaped configuration.

The memory cells, the drain-side select transistor STD, and the source-side select transistor STS are vertical transistors through which the current flows in the Z-direction.

The drain-side selection gate SGD functions as the gate electrode (the control gate) of the drain-side select transistor STD. An insulating film (not shown) that functions as the gate insulator film of the drain-side select transistor STD is provided between the drain-side selection gate SGD and the channel body 20. The channel body of the drain-side select transistor STD is connected to the bit line BL above the drain-side selection gate SGD.

The source-side selection gate SGS functions as the gate electrode (the control gate) of the source-side select transistor STS. An insulating film (not shown) that functions as the gate insulator film of the source-side select transistor STS is provided between the source-side selection gate SGS and the channel body 20. The channel body 20 of the source-side select transistor STS is connected to the source line SL above the source-side selection gate SGS.

A back gate transistor BGT is provided at the connecting portion JP of the memory string MS. The back gate BG functions as the gate electrode (the control gate) of the back gate transistor BGT. The memory film 30 that is provided inside the back gate BG functions as the gate insulator film of the back gate transistor BGT.

Multiple memory cells that have the electrode layers WL of each layer as control gates are provided between the drain-side select transistor STD and the back gate transistor BGT. Similarly, multiple memory cells that have the electrode layers WL of each layer as control gates are provided between the source-side select transistor STS and the back gate transistor BGT.

The multiple memory cells, the drain-side select transistor STD, the back gate transistor BGT, and the source-side select transistor STS are connected in series via the channel body 20 and are included in one memory string MS having a U-shaped configuration. By the memory string MS being multiply arranged in the X-direction and the Y-direction, multiple memory cells are provided three-dimensionally in the X-direction, the Y-direction, and the Z-direction.

The memory cell array 1 is provided in the memory array region of the substrate 10. As shown in FIG. 1, the multiple columnar portions CL are disposed in a matrix configuration in the X-direction and the Y-direction in the memory array region.

FIG. 5A corresponds to a cross section of the memory cell array 1 of FIG. 1 along the Y-direction. The memory string MS having the U-shaped configuration is formed by the lower ends of the mutually-adjacent pair of columnar portions CL being linked in the Y-direction.

As shown in FIG. 1, the bit line BL that extends in the Y-direction is provided on the columnar portions CL arranged in the Y-direction. The upper end of one columnar portion CL selected from the pair of columnar portions CL of the memory string MS having the U-shaped configuration is connected to the bit line BL. The upper end of the columnar portion CL of the other columnar portion CL selected from the pair of columnar portions CL is connected to the source line SL that is shown in FIG. 2 and provided on the upper end of the columnar portion CL of the other columnar portion.

In the layout of the example shown in FIG. 1, two layer selection portions 15 are provided on two sides of the memory cell array 1 in the X-direction. The select transistors 22a to 22f are provided between the memory cell array 1 and the layer selection portions 15.

For example, the select transistors 22a to 22c are provided between the memory cell array 1 and the layer selection portion 15 on the left side of FIG. 1. The select transistors 22d to 22f are provided between the memory cell array 1 and the layer selection portion 15 on the right side of FIG. 1.

FIG. 5B is a schematic cross-sectional view of the region where the select transistors 22a to 22c on the left side of FIG. 1 are provided.

FIG. 5B corresponds to a cross section of FIG. 1 along the Y-direction. The configurations of the select transistors 22d to 22f on the right side of FIG. 1 are similar to those of the select transistors 22a to 22c.

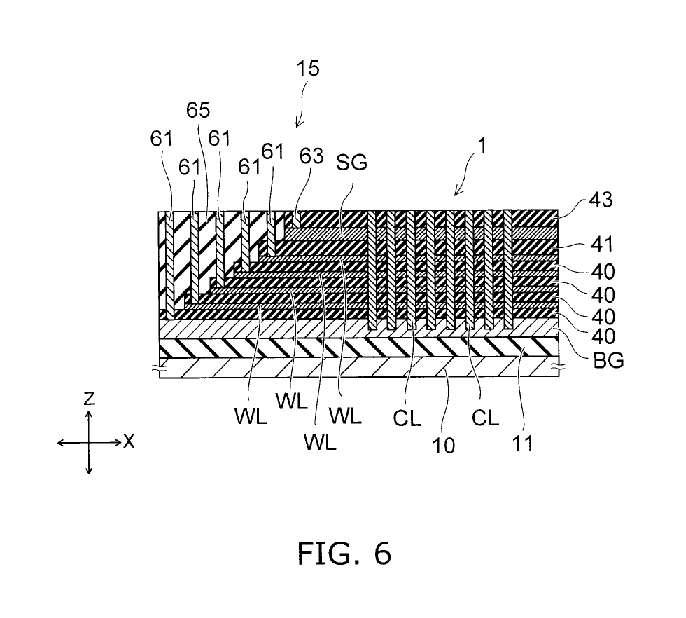

FIG. 6 is a schematic cross-sectional view of a portion from the memory array region to the region where the layer selection portion 15 on the left side of FIG. 1 is formed.

FIG. 6 corresponds to a cross section of FIG. 1 along the X-direction. In FIG. 1, the configuration of the layer selection portion 15 on the right side is similar to that of the layer selection portion 15 on the left side.

The stacked body that includes the multiple electrode layers WL and the multiple insulating layers 40 also is provided in the layer selection portions 15 and in the regions where the select transistors 22a to 22f are provided.

As shown in FIG. 1, the stacked body includes multiple line portions 13 extending in the X-direction. The multiple line portions 13 are arranged in the Y-direction that intersects (e.g., is orthogonal to) the X-direction. The insulating separation film 42 shown in FIG. 5A is provided between the mutually-adjacent line portions 13 in the Y-direction.

In the regions where the select transistors 22a to 22f are provided as shown in FIG. 5B, a gate electrode 23 is provided between the mutually-adjacent line portions 13 in the Y-direction with a gate insulator film 24 interposed between the gate electrode 23 and the line portions 13.

The pair of columnar portions CL of which the lower ends are linked is provided respectively in a pair of line portions 13 adjacent to each other in the Y-direction with the insulating separation film 42 interposed between the pair of line portions 13. The channel body 20 and the memory film 30 extend in the Z-direction (the stacking direction) through the line portion 13 in the memory array region.

As shown in FIG. 6, the electrode layer WL of the memory cell array 1, the electrode layer WL in the regions where the select transistors 22a to 22f are provided, and the electrode layer WL of the layer selection portion 15 are continuous as a single body. One line portion 13 is continuous with the layer selection portion 15 at only one X-direction side end portion.

As shown in FIG. 6, the stacked body is formed in a stairstep configuration in the layer selection portion 15. In other words, the X-direction end portions of the electrode layers WL of each layer are formed in a stairstep configuration. An inter-layer insulating layer 65 is provided on the stairstep structure portion.

Multiple contact portions 61 are provided in the layer selection portion 15 and connected to the electrode layers WL of each layer formed in the stairstep configuration. The contact portions 61 pierce the inter-layer insulating layer 65 to be connected to the electrode layers WL of each layer having the stairstep configuration. The back gate BG also is connected to the contact portion 61 provided to pierce the inter-layer insulating layer 65.

The selection gate SG is connected to a contact portion 63 provided to pierce the insulating layer 43 on the selection gate SG.

FIG. 4 is an enlarged schematic view of, for example, the region of FIG. 1 where the select transistor 22a is provided. The structures of the other select transistors 22b to 22f are similar to that of the select transistor 22a.

The select transistor 22a includes the gate electrode 23 and the gate insulator film 24. The gate electrode 23 is provided on the side wall of the line portion 13 between the memory cell array 1 and the layer selection portion 15 and extends in the stacking direction (the Z-direction) as shown in FIG. 5B. The gate insulator film 24 is provided between the gate electrode 23 and the line portion 13.

The gate electrode 23 is provided on two sides of the line portion 13 in the Y-direction on the side-wall sides of the line portion 13. Also, as shown in FIG. 5B, the gate electrode 23 is provided on the line portion 13. In other words, in the regions where the select transistors 22a to 22f are provided, the side walls and upper surface of the line portion 13 are covered with the gate electrode 23 with the gate insulator film 24 interposed between the gate electrode 23 and the side walls and upper surface.

Each of the line portions 13 includes multiple electrode layers WL stacked with the insulating layers 40 interposed. The channels of the select transistors 22a to 22f are formed in the electrode layers WL of each of the line portions 13 in the regions where the gate electrodes 23 are provided on two sides of the electrode layer WL with the gate insulator film 24 interposed.

As shown in FIG. 4, an impurity diffusion region 17 that is used as the source/drain region of the select transistor 22a is formed in the electrode layer WL in the select transistor formation region. The impurity concentration of the impurity diffusion region 17 is higher than the impurity concentration of the electrode layer WL of the memory cell array 1.

Contact portions 27 that are schematically shown in FIG. 1 are provided respectively for the gate electrode 23 of the select transistor 22a that is provided on two sides of the line portion 13. The gate electrode 23 of the select transistor 22a is connected to a gate interconnect 25a via the contact portions 27.

Similarly, for the other select transistors 22b to 22f as well, the gate electrodes 23 are connected to gate interconnects 25b to 25f via the contact portions 27.

The gate interconnects 25a to 25f are provided on the stacked body with a not-shown insulating layer interposed between the stacked body and the gate interconnects 25a to 25f.

The multiple line portions 13 include the line portions 13 that are connected to the layer selection portion 15 on the left end side of FIG. 1 and the line portions 13 that are connected to the layer selection portion 15 on the right end side of FIG. 1. In FIG. 1, the line portions 13 that are connected to the layer selection portion 15 on the left side are arranged alternately in the Y-direction with the line portions 13 connected to the layer selection portion 15 on the right side.

The select transistors 22a to 22f are provided respectively for the line portions 13 in regions on the sides where the line portions 13 are connected to the layer selection portions 15. The select transistors 22a to 22f switch the current paths of the electrode layers WL between the layer selection portions 15 and the memory cell array 1 ON/OFF.

The drain-side selection gate SGD switches the conduction between the bit line BL and the channel body 20 ON/OFF. The source-side selection gate SGS switches the conduction between the source line and the channel body 20 ON/OFF.

The levels of the electrode layers WL are selected via the contact portions 61 of the layer selection portion 15 shown in FIG. 6. The line portions 13 of the electrode layers WL are selected by the select transistors 22a to 22f.

In FIG. 1, for example, when the desired gate potential is applied to the gate electrode 23 of the select transistor 22a via the gate interconnect 25a and the contact portions 27, channels are formed in the electrode layers WL interposed between the gate electrode 23. Accordingly, the contact portions 61 of the layer selection portion 15 are electrically connected to the electrode layers WL of the memory cell array 1 via the channels; and the desired potential can be applied to the electrode layers WL of the selected memory cells.

Also, when the desired potential is applied to the drain-side selection gate SGD via the contact portion 63 shown in FIG. 6, the channel body 20 can be electrically connected to the bit line BL. When the desired potential is applied to the source-side selection gate SGS via the contact portion 63, the channel body 20 can be electrically connected to the source line SL.

Further, when the desired potential is applied to the back gate BG via the contact portion 61, the back gate transistor BGT is switched ON; and the channel bodies 20 of the pair of columnar portions CL are electrically connected via the channel body 20 of the connecting portion W.

For example, an erasing operation of data will now be described. In a semiconductor memory device having a general two-dimensional structure, the electrons that are injected into the floating gates are removed by increasing the substrate potential. However, in a semiconductor memory device having a three-dimensional structure such as that of the embodiment, the channels of the memory cells are not connected directly to the substrate. Therefore, a method has been proposed in which the channel potential of the memory cells is boosted by utilizing the GIDL (Gate Induced Drain Leakage) current occurring in the channel at the end of the selection gate SG.

In other words, the channel potential is increased by supplying, to the channel body 20, the holes generated in the high-concentration impurity diffusion region formed in the channel body of the upper end portion vicinity of the selection gate SG by applying a high voltage. By setting the potential of the electrode layers WL to, for example, the ground potential (0 V), the potential difference between the channel body 20 and the electrode layers WL causes the electrons of the charge storage film 32 to be removed or the holes to be injected into the charge storage film 32; and the erasing operation is performed.

It has been proposed to perform the erasing by block units that include multiple memory strings MS. In such a case, the erasing potential is applied also to the electrode layers WL of the unselected memory cells that are not to be erased. In the case where one block size increases as the number of stacks of the electrode layers WL increases, the unselected memory cells that undergo voltage stress in the erasing increase; and there is a risk that the read disturbance may increase.

However, according to the embodiment, individual line portions 13 can be switched ON/OFF independently by the select transistors 22a to 22f. By switching the select transistors 22a to 22f OFF for the electrode layers WL of the unselected line portions 13, the electrical connection to the contact portions 61 of the layer selection portions 15 can be broken.

Although conventional erasing is performed collectively for block units that include multiple line portions 13, according to the embodiment, the erasing can be performed by units of the selected line portions 13; and the erasing unit can be small. Therefore, the number of times the voltage stress is applied to the unselected memory cells in the erasing can be reduced. As a result, the read disturbance can be suppressed; and the reliability of the semiconductor memory device can be increased.

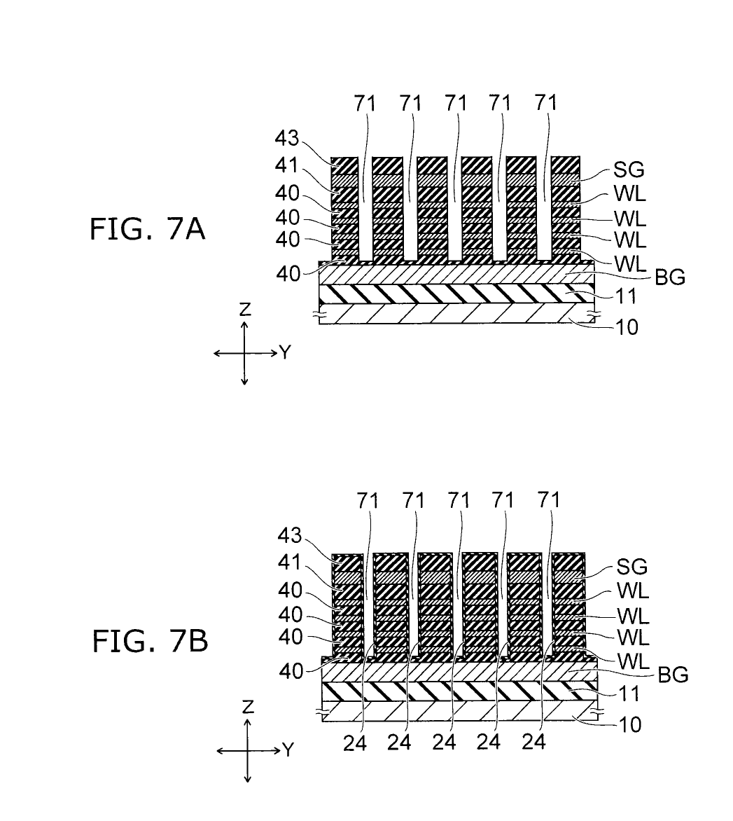

A method for forming the select transistors 22a to 22f of the first embodiment will now be described with reference to FIGS. 7A and 7B.

First, the stacked body shown in FIG. 7A is formed on the substrate 10. The layers of the stacked body are formed by, for example, CVD (Chemical Vapor Deposition).

Then, a slit 71 is made in the stacked body by, for example, RIE (Reactive Ion Etching) using a not-shown resist mask. The slit 71 divides, in the Y-direction, the stacked body that is higher than the back gate BG. In other words, as shown in FIG. 1, the multiple line portions 13 are formed to extend in the X-direction and to be arranged in the Y-direction.

For one line portion 13, the end portion on the side not connected to the layer selection portion 15 is separated from the layer selection portion 15 that is on the opposite side and is not to be connected.

Then, after forming a resist mask on the entire surface of the stacked body, openings are made in the regions where the select transistors are to be formed. The memory array region and the layer selection portion formation regions are covered with the resist mask.

In this state, the source/drain region 17 shown in FIG. 4 is formed in the electrode layers WL in the select transistor formation region by ion implantation or vapor phase diffusion.

If necessary, the thresholds of the select transistors are controlled by introducing an impurity to the regions used to form the channels of the select transistors by ion implantation or vapor phase diffusion.

Then, as shown in FIG. 7B, the gate insulator film 24 is formed on the inner wall of the slit 71 in the select transistor formation region. The gate insulator film 24 is formed on the side walls and upper surface of the line portion 13 and between adjacent line portions 13.

The gate insulator film 24 is, for example, a silicon oxide film, a silicon nitride film, a silicon oxynitride film, a stacked film of a silicon oxide film and a silicon nitride film, etc., formed by CVD.

After forming the gate insulator film 24, the gate electrode 23 is filled into the slit 71 as shown in FIG. 5B. The gate electrode 23 is, for example, polycrystalline silicon formed by CVD.

Holes are made in the line portions 13 in the memory array region to extend in the stacking direction of the stacked body. Recesses are made in the back gate BG in the memory array region prior to forming the stacked body; and the stacked body is stacked on the back gate BG after filling a sacrificial film into the recesses.

The holes recited above are made to reach the sacrificial film; and a memory hole having a U-shaped configuration is made by removing the sacrificial film by etching via the holes to cause the recess and a pair of holes to communicate. The channel body 20 is formed inside the memory hole with the memory film 30 interposed.

### Second Embodiment

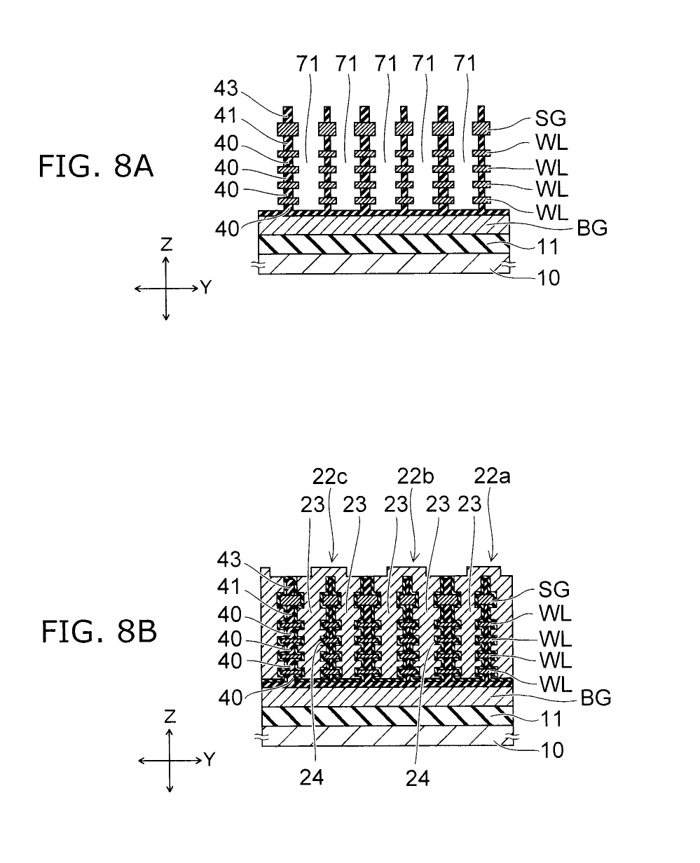

Similarly to FIG. 5B, FIG. 8B is a schematic cross-sectional view along the Y-direction of the region of FIG. 1 where the select transistors 22a to 22c are provided.

According to the second embodiment shown in FIG. 8B, the gate electrode 23 of the select transistor is provided also on the upper surface and lower surface of the electrode layer WL.

After making the slit 71 shown in FIG. 7A and prior to forming the gate insulator film 24, the widths of the insulating layers 40, 41, and 43 in the regions where the select transistors are provided are reduced by etching as shown in FIG. 8A.

For example, the insulating layers 40, 41, and 43 are etched by chemical liquid processing using dilute hydrofluoric acid. Or, the insulating layers 40, 41, and 43 may be etched by RIE.

The etching of the insulating layers 40, 41, and 43 progresses not only in the Y-direction but also in the X-direction. Therefore, the distance from the memory strings MS furthest on the select transistor side to the select transistors 22a to 22f is ensured to be the distance that the insulating layers 40, 41, and 43 of the memory cell array 1 are not shrunk.

As shown in FIG. 8A, in the case where the gate electrode 23 is formed after shrinking the insulating layers 40, 41, and 43, a gate-around transistor structure is obtained in which the side surfaces, upper surface, and lower surface of the electrode layer WL are covered with the gate electrode 23 as shown in FIG. 8B. Therefore, the channel controllability by the gate electrode 23 can be improved.

### Third Embodiment

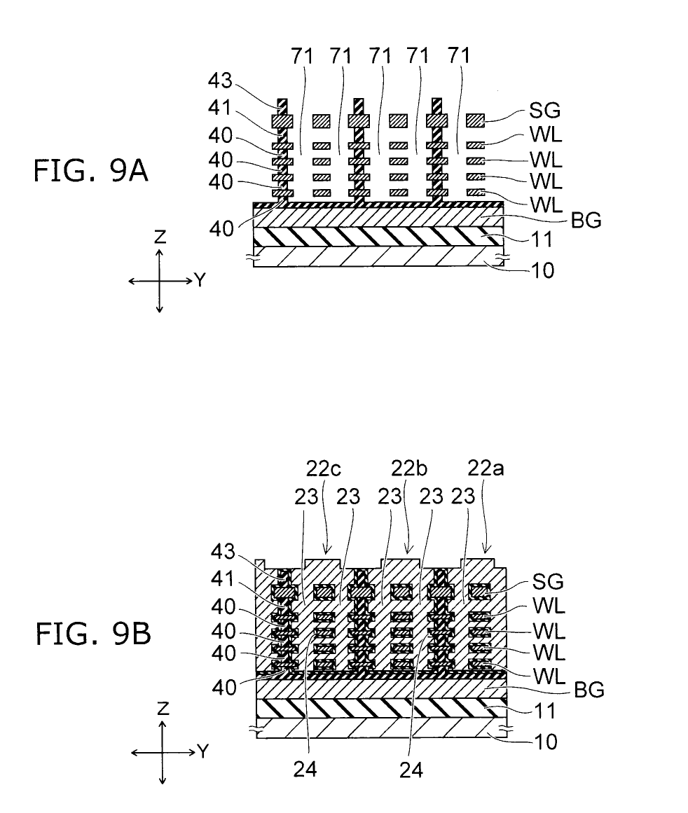

Similarly to FIG. 5B, FIG. 9B is a schematic cross-sectional view along the Y-direction of the region of FIG. 1 where the select transistors 22a to 22c are provided.

According to the third embodiment shown in FIG. 9B, the gate electrode 23 is provided completely around the upper surface, lower surface, and side surfaces of the electrode layer WL in the regions where the select transistors 22a to 22f are provided.

The insulating layers 40, 41, and 43 are removed completely by the etching of the insulating layers 40, 41, and 43 progressing further from the state of FIG. 8A of the second embodiment. The electrode layers WL that are in the regions where the select transistors 22a to 22f are provided are in a state of floating in space and are supported as beams by the electrode layers WL of the memory cell array 1 and the electrode layers WL of the layer selection portions 15.

According to the third embodiment, a gate-all-around transistor structure is obtained in which the gate electrode 23 is provided completely around the side surfaces, upper surface, and lower surface of the electrode layer WL. Therefore, the channel controllability by the gate electrode 23 can be improved further.

### Fourth Embodiment

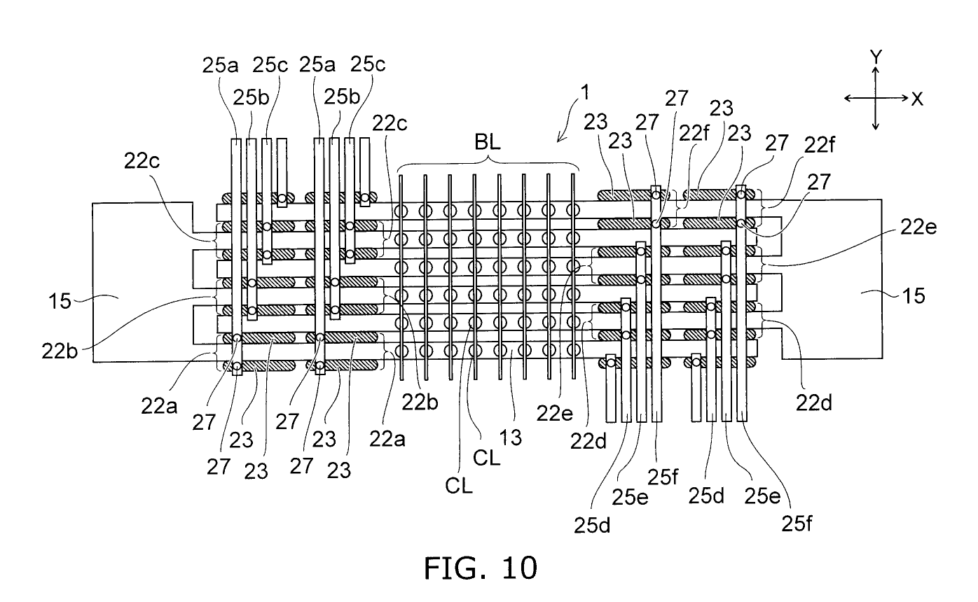

FIG. 10 is a schematic plan view of a semiconductor memory device of a fourth embodiment.

Similarly to the first embodiment, the semiconductor memory device of the fourth embodiment includes the memory cell array 1, the layer selection portion 15, and the select transistors 22a to 22f provided in the regions between the memory cell array 1 and the layer selection portion 15.

In the fourth embodiment, multiple (e.g., in FIG. 10, two) select transistors are provided for one line portion 13 and arranged in the X-direction.

By operating multiple select transistors for one line portion 13, the current flowing in the electrode layers WL in the regions where the select transistors are provided can be cut off easily; and the ON/OFF controllability can be improved.

### Fifth Embodiment

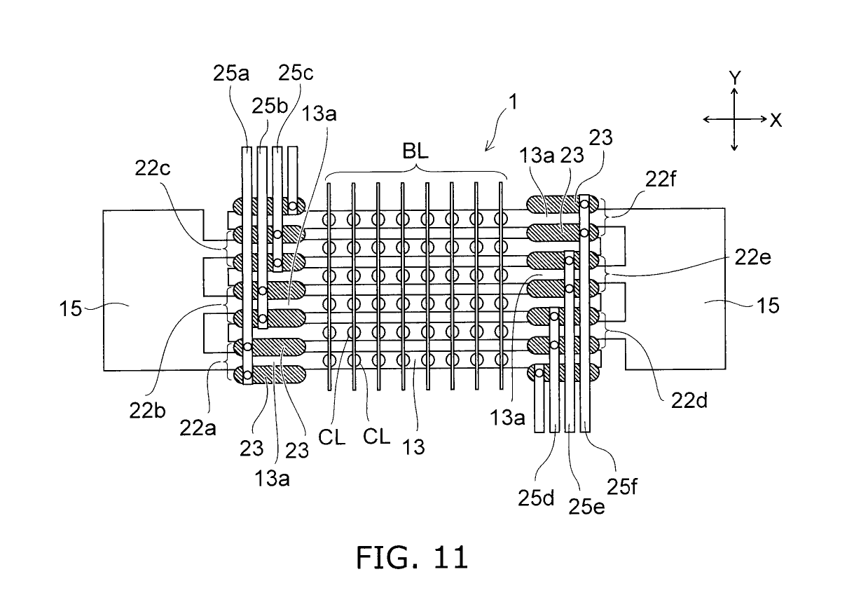

FIG. 11 is a schematic plan view of a semiconductor memory device of a fifth embodiment.

Similarly to the first embodiment, the semiconductor memory device of the fifth embodiment includes the memory cell array 1, the layer selection portion 15, and the select transistors 22a to 22f provided in the region between the memory cell array 1 and the layer selection portion 15.

In the fifth embodiment, the widths (the widths in the Y-direction) of the electrode layers WL are finer in the regions where the select transistors 22a to 22f are provided than in the memory cell array 1.

By designing the mask for making the slit 71 in the stacked body shown in FIG. 7A so that the width of one portion 13a of the line portion 13 is narrow as shown in FIG. 11, the widths of the electrode layers WL can be finer in the regions where the select transistors 22a to 22f are provided.

By making the widths of the electrode layers WL interposed between the gate electrodes 23 of the select transistors 22a to 22f fine, the controllability of the gate electrodes 23 for the electrode layers WL is better; and the electric field can be applied easily.

Also, the region of the slit 71 into which the gate electrode 23 is filled is wider; and the gate electrode 23 is formed easily.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device, comprising:
a substrate;
a stacked body including a plurality of electrode layers and a plurality of insulating layers stacked alternately on the substrate, the stacked body including a plurality of line portions and a layer selection portion, the plurality of line portions extending in a first direction in a plane parallel to the substrate, the layer selection portion including a plurality of contact portions connected to the electrode layers at an end of the line portions in the first direction;
a channel body provided in the line portions to extend in a stacking direction of the stacked body;
a charge storage film provided between the channel body and the electrode layers; and
a select transistor provided between a memory array region and the layer selection portion, the channel body and the charge storage film being provided in the memory array region,
the select transistor including:
a gate electrode provided on a side wall of one of the line portions between the memory array region and the layer selection portion, the gate electrode extending in the stacking direction; and
a gate insulator film provided between the gate electrode and the line portions.

2. The device according to claim 1, wherein the gate electrode is provided on two side walls of one of the line portions in a width direction of the line portions.

3. The device according to claim 1, wherein the gate electrode is provided between the line portions.

4. The device according to claim 1, further comprising a contact portion connected to the gate electrode.

5. The device according to claim 1, wherein the gate electrode is provided on an upper surface of the electrode layers and a lower surface of the electrode layers.

6. The device according to claim 1, wherein
the electrode layers in the memory array region, the electrode layers in a region where the select transistor is provided, and the electrode layers of the layer selection portion are continuous as a single body, and
the gate electrode is provided around an upper surface of the electrode layers, a lower surface of the electrode layer, and a side surface of the electrode layers in the region where the select transistor is provided.

7. The device according to claim 1, wherein a plurality of the select transistors is provided between the memory array region and the layer selection portion to be arranged in the first direction for one of the line portions.

8. The device according to claim 1, wherein a width of the electrode layers is narrower in a region where the select transistor is provided than in the memory array region.

9. The device according to claim 1, wherein
the channel body and the charge storage film include:
a pair of columnar portions extending through the stacked body in the stacking direction; and
a connecting portion connecting lower ends of the pair of columnar portions,
each of the pair of columnar portions connected via the connecting portion being provided in each of a pair of mutually-adjacent line portions, the pair of mutually-adjacent line portions being adjacent to each other in a second direction intersecting the first direction on two sides of an insulating separation film.

10. The device according to claim 1, wherein the electrode layers are semiconductor layers.

11. The device according to claim 10, wherein a source/drain region is provided in the electrode layers in a region where the select transistor is provided, an impurity concentration of the source/drain region being higher than an impurity concentration of the electrode layers in the memory array region.

12. The device according to claim 1, wherein
the line portions includes first line portions and second line portions, the first line portions and the second line portions being arranged alternately in a second direction intersecting the first direction,
the layer selection portion includes a first layer selection portion and a second layer selection portion, the memory array region being provided between the first layer selection portion and the second layer selection portion, the first layer selection portion being connected to the first line portions, the second layer selection portion being connected to the second line portions, and
the select transistor includes a first select transistor and a second select transistor, the first select transistor being provided between the memory array region and the first layer selection portion, the second select transistor being provided between the memory array region and the second layer selection portion.

13. The device according to claim 9, wherein a plurality of the columnar portions is disposed in a matrix configuration in the first direction and the second direction in the memory array region.

14. The device according to claim 13, wherein
a bit line is provided to extend in the second direction on a plurality of the columnar portions arranged in the second direction, and
an upper end of one columnar portion selected from the pair of columnar portions connected via the connecting portion is connected to the bit line, and an upper end of the other columnar portion selected from the pair of columnar portions is connected to a source line provided on the upper end of the other columnar portion.

15. A method for manufacturing a semiconductor memory device, comprising:
forming a stacked body including a plurality of electrode layers and a plurality of insulating layers stacked alternately on a substrate, the stacked body including a plurality of line portions and a layer selection portion, the plurality of line portions extending in a first direction in a plane parallel to the substrate, the layer selection portion including a plurality of contact portions connected to the electrode layers at an end of the line portions in the first direction; and
making a hole in the line portions of the stacked body in a memory array region to extend in a stacking direction of the stacked body;
forming a film on a side wall of the hole, the film including a charge storage film;
forming a channel body on a side wall of the film; and
forming a select transistor between the memory array region and the layer selection portion,
the forming of the select transistor including:
forming a gate insulator film on a side wall of the line portions between the memory array region and the layer selection portion; and
forming a gate electrode on a side wall of the gate insulator film.

16. The method according to claim 15, wherein the forming of the select transistor further includes introducing an impurity to the electrode layers of a region where the select transistor is provided.

17. The method according to claim 15, wherein
widths of the insulating layers in a region where the select transistor is provided are reduced by etching prior to forming the gate insulator film, and
the gate insulator film and the gate electrode are formed also on an upper surface of the electrode layers and a lower surface of the electrode layers.

18. The method according to claim 17, wherein
the insulating layers on and under the electrode layers are removed completely by the etching, and
the gate insulator film and the gate electrode are provided around an upper surface of the electrode layers, a lower surface of the electrode layers, and side surfaces of the electrode layers.
